(19) United States
(12) Patent Application Publication
(10) Pub. No.: US 2009/0035879 A1
(43) Pub. Date: Feb. 5, 2009

(54) LASER DICING DEVICE AND LASER DICING METHOD

(75) Inventor: Yasuyuki Sakaya, Mitaka-shi (JP)

Correspondence Address: ROBERTS MLOTKOWSKI SAFRAN & COLE, P.C.;Intellectual Property Department, P.O. Box 10064, MCLEAN, VA, 22102-8064, US

(73) Assignee: TOKYO SEIMITSU CO., LTD., Mitaka-shi, Tokyo (JP)

(21) Appl. No.: 12/088,036

(22) PCT Filed: Sep. 26, 2006
(86) PCT No.: PCT/JP2006/319035

§ 371 Date: Mar. 25, 2008

(30) Foreign Application Priority Data
Sep. 28, 2005 (JP) 2005-282587

(51) Int. Cl. B23K 26/02; H01L 21/302; H01L 21/66

(52) U.S. Cl. 438/7; 219/121.67; 219/121.72; 257/E21.53; 257/E21.214

(57) ABSTRACT

An object is to provide a laser dicing apparatus and a laser dicing method capable of speedily performing high-quality dicing without causing any working defect even in a case where wafers varying in thickness are supplied. The laser dicing apparatus is provided with a measuring device which measures thickness of a wafer W, a recording device which stores a database in which modified region forming conditions associated with different thicknesses of the wafer W are described, and a control device which controls the laser dicing apparatus by automatically selecting, from the database, on the basis of the thickness of the wafer measured by the measuring device, the modified region forming conditions corresponding to the measured thickness of the wafer W. The optimum modified region forming conditions are thereby automatically set, so that even in a case where wafers W differing in thickness are supplied, high-quality dicing can be speedily performed without causing a working defect.

### TECHNICAL FIELD

The present invention relates to a dicing apparatus and a dicing method for manufacturing chips for semiconductor devices, electronic components and the like and, more particularly, to a laser dicing apparatus and a laser dicing method using laser light.

### BACKGROUND ART

Conventionally, a dicing apparatus for cutting a wafer by forming a ground groove in the wafer with a thin grinding wheel formed of fine diamond abrasive grains and having a thickness of about 30 μm is used to divide a wafer having semiconductor devices, electronic components or the like formed on its surface into individual chips.

In the dicing apparatus, the thin grinding wheel (hereinafter referred to as a dicing blade) is rotated at a high speed (30,000 to 60,000 rpm) to grind the wafer and to complete cutting (full cutting) or incomplete cutting (half cutting or semi-full cutting).

Since the wafer is a highly brittle material, grind-machining with this dicing blade, however, is brittle-mode machining causing chipping in the front and back surfaces of the wafer. This chipping is a cause of a reduction in performance of divided chips. With chipping caused in the back surface in particular, there is a serious problem that a crack progresses gradually to an inner portion.

With this problem in view, a laser dicing apparatus and a laser dicing method have been proposed in which the conventional cutting with a dicing blade is replaced with introducing laser light focused on an internal portion of the wafer, forming a plurality of modified regions in the wafer by multi-photon absorption, and cutting and dividing the wafer into individual chips (see, for example, Japanese Patent Laid-Open No. 2004-111946).

The technique proposed in the above-mentioned Japanese Patent Laid-Open No. 2004-111946 requires previously setting the thickness of a wafer to be diced in the laser dicing apparatus for determination of, for example, positions at which modified regions are to be formed in the wafer and the number or density of modified regions.

In the process of manufacturing a semiconductor device, an electronic component or the like, polishing and grinding of the front or back surface of a wafer is ordinarily performed. In this process, working is performed by setting the thickness of a wafer after working. However, it is difficult to equalize in thickness all wafers after working, and variation in thickness results. Therefore, if working is continued under modified region forming conditions corresponding to a certain thickness, a working defect occurs when a wafer differing in thickness is supplied. Therefore, there is a need for measurement of the thickness of each wafer and reset of modified region forming conditions most suitable for the thickness performed by an operator.

The present invention has been made in consideration of such a problem, and an object of the present invention is to provide a laser dicing apparatus and a laser dicing method capable of speedily performing high-quality dicing without causing any working defect even in a case where wafers differing in thickness are supplied.

### DISCLOSURE OF THE INVENTION

To achieve the above-described object, according to the present invention, there is provided a laser dicing apparatus which introduces laser light through a surface of a wafer to form a modified region in the wafer, the apparatus characterized by comprising a measuring device which measures thickness of the wafer, a recording device which stores a database in which modified region forming conditions associated with different thicknesses of the wafer are described, and a control device which controls the laser dicing apparatus by automatically selecting the modified region forming conditions corresponding to the thickness of the wafer from the database on the basis of the thickness of the wafer measured by the measuring device.

The above-described invention is characterized in that the modified region forming conditions are a number of the modified regions to be formed, positions of the modified regions to be formed, thickness of the modified regions to be formed, speed at which the laser light is moved, frequency of the laser light and shape of the laser light.

Further, the present invention is also characterized in that, in a laser dicing apparatus in which laser light is introduced through a surface of a wafer to form a modified region in the wafer, a control device automatically selects, on the basis of the thickness of the wafer measured by a measuring device, from modified region forming conditions associated with different thicknesses of the wafer and described in a database stored in a recording device in advance, and laser dicing is performed under the selected modified region forming conditions.

According to the present invention, the thickness of the wafer before dicing is automatically measured by the contact-type or noncontact-type measuring device provided in the laser dicing apparatus. A database in which modified region forming conditions associated with different thicknesses of the wafer, including a number of modified regions to be formed, positions of the modified regions to be formed, thickness of the modified regions to be formed, speed at which the laser light is moved, frequency of the laser light and shape of the laser light is stored in the recording device.

The control device selects, on the basis of the measured thickness of the wafer, the modified region forming conditions corresponding to the measured thickness of the wafer from the modified region forming conditions described in the database stored in the recording device, and automatically sets the selected modified region forming conditions in the laser dicing apparatus. The laser dicing apparatus performs working on the wafer under the set modified region forming conditions.

In this way, even in a case where wafers varying in thickness are successively supplied to the laser dicing apparatus, the wafer thickness is automatically measured and dicing is performed by selecting the optimum modified region forming conditions from the modified region forming conditions prepared in advance. Therefore, high-quality dicing can be speedily performed without causing a working defect due to an abrupt change in thickness.

In the laser dicing apparatus and laser dicing method according to the present invention, as described above, the wafer thickness is automatically measured to set the optimum modified region forming conditions, so that even in a case where wafers differing in thickness are supplied, high-quality dicing can be speedily performed without causing a working defect.

### BRIEF DESCRIPTION OF THE DRAWINGS

FIG. 1 is a top view schematically showing the construction of a laser dicing apparatus according to the present invention;

FIG. 2 is a side view for explaining the construction of a laser head;

FIG. 3 is a schematic diagram for explaining a modified region formed in the vicinity of a light condensation point in a wafer;

FIG. 4 is a side view showing the construction of a measuring device;

FIG. 5 is a side view showing the construction of another measuring device;

FIG. 6 is a perspective view showing the wafer mounted on a frame; and

FIG. 7 is a flowchart showing a laser dicing method according to the present invention.

### DESCRIPTION OF SYMBOLS

10 Laser dicing apparatus
11 Base
12 Chuck table
13 Elevator
14 Standby table
15 X-guide base
16 Measuring device
17 Measuring probe
18 Displacement measuring device
19 Main body
20 Air cylinder
21 Control device
22 Recording device
31 Laser head
31D Condenser lens
32 Holder
F Frame
L Laser light
P, P1, P2 Modified region
T Dicing tape
W Wafer

### BEST MODE FOR CARRYING OUT THE INVENTION

Preferred embodiments of a laser dicing apparatus and a laser dicing method according to the present invention will be described in detail with reference to the accompanying drawings.

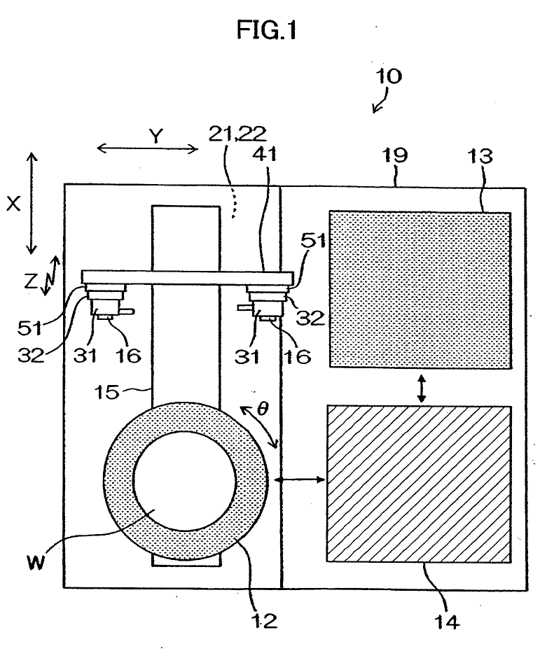

First, a laser dicing method according to the present invention will be described. FIG. 1 is a top view schematically showing the construction of the laser dicing apparatus.

A laser dicing apparatus 10 has in a main body 19 a chuck table 12, an X-guide base 15, a Y-guide base 41, a Z-guide base 51, an elevator 13, a standby table 14, a laser head 31, a measuring device 16, a control device 21 and a recording device 22.

The chuck table 12, onto which a wafer W is attracted and mounted, is rotated in the direction of arrow θ by means of a θ-rotation shaft not illustrated and is working-fed in the direction of arrow X with an X-table mounted on the X-guide base but not illustrated.

The Y-guide base 41 is provided above the chuck table 12. Two Y-tables not illustrated are provided on the Y-guide base 41, and Z-guide rails 51 are respectively attached to the Y-tables.

A Z-table not illustrated is provided on each of the Z-guide rails 51. The laser head 31 is attached to each Z-table by means of a holder 32. The two laser heads 31 are moved in the Z-direction independently of each other and are indexing-fed independently in the Y-direction.

The elevator 13 contains a cassette containing a wafer W and is vertically moved to enable the wafer W to be supplied onto the standby table 15 by a conveying device not illustrated. The standby table is provided generally at the same height as that of the chuck table 12. Various necessary processings are performed on the wafer W mounted on the standby table before and after working.

The measuring device 16 is a contact-type or noncontact-type displacement measuring device. By the measuring device 16, the height of each wafer W is measured from the amount of displacement.

The control device 21 housed in the main body 19 is constituted by a CPU, a memory, input/output circuit section, etc. The control device 21 calls up information necessary for working from a database stored in the recording device 22 also housed in the main body 19, and controls the operation of each portion of the laser dicing apparatus 10.

The laser dicing apparatus 10 has other components including a wafer transport device, an operation panel, a television monitor and indicating lamps, which are not illustrated.

On the operation panel, switches for operating portions of the laser dicing apparatus 10 and a display device are mounted. The television monitor displays a wafer image taken with a CCD camera not illustrated and, program contents, various messages and the like. The indicating lamps indicate states of operation such as on-working, completion of working and an emergency stop.

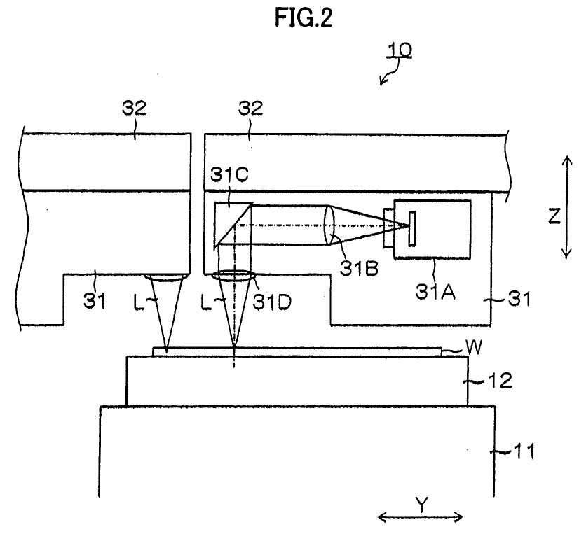

FIG. 2 is a side view for explaining the construction of the laser head 31. The laser head 31 is positioned above the wafer W mounted on the chuck table 12 provided on a base 11 of the laser dicing apparatus 10 so as to apply laser light L to the wafer W.

The laser head 31 is constituted by a laser oscillator 31A, a collimator lens 31B, a mirror 31C and a condenser lens 31D. As shown in FIG. 2, light L oscillated from the laser oscillator 31A is formed into parallel rays in a horizontal direction by the collimator lens 31B, reflected in a vertical direction by the mirror 31C and condensed by the condenser lens 31D.

If the point on which laser light L is condensed is set in wafer W mounted on the chuck table 12 in the thickness direction of wafer W, the energy of laser light L transmitted through the surface of wafer W is concentrated on the condensation point to form a modified region such as a cracked region, a molten region or a refractive-index-changed region due to multiphoton absorption in the vicinity of the condensation point in the wafer.

Also, the laser head 31 has an inclining mechanism not illustrated, and can apply laser light L to the wafer surface while inclining laser light L at an arbitrary angle from the wafer surface.

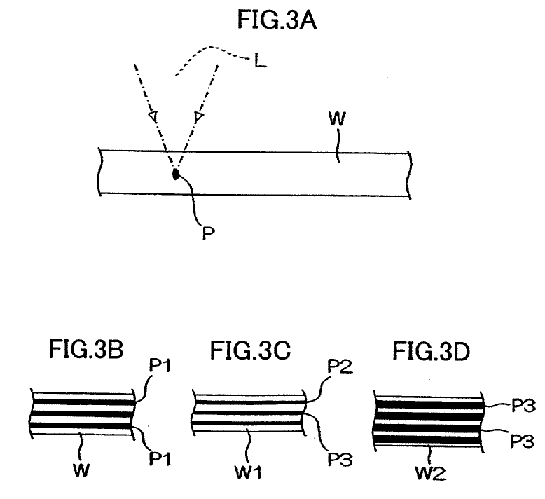

FIGS. 3(a), 3(b), 3(c), and 3(d) are schematic diagrams for explaining modified regions formed in the vicinity of the condensation point in the wafer. FIG. 3(a) shows a state in which a modified region P is formed at the condensation point by laser light L introduced into the wafer W. The wafer W is moved in the horizontal direction in this state to continuously form the modified region P, thereby forming a continuous modified region P1, as shown in FIG. 3(b).

A plurality of modified regions P1 are formed by changing the laser light L condensation point. The wafer W divides by spontaneous breaking starting from modified regions P1 or is divided by breaking from modified regions P1 caused by applying a small external force. In this case, the wafer W can be easily divided into chips without causing chipping in the front and back surfaces.

In the case of dividing a wafer W1 thinner than the wafer W, the modified region forming conditions are changed and the wafer W1 is divided by forming modified regions P2 narrower than modified regions P1 (FIG. 3(c)). In the case of dividing a wafer W2 thicker than the wafer W, the modified region forming conditions are changed and the wafer W2 is divided by forming a larger number of modified regions P3 wider than modified regions P1 in comparison with the case of the wafer W (FIG. 3(d)).

In this way, the wafer W is cut by forming modified regions most suitable for the corresponding one of different thicknesses, so that defects such as those due to chip dividing failure are not caused.

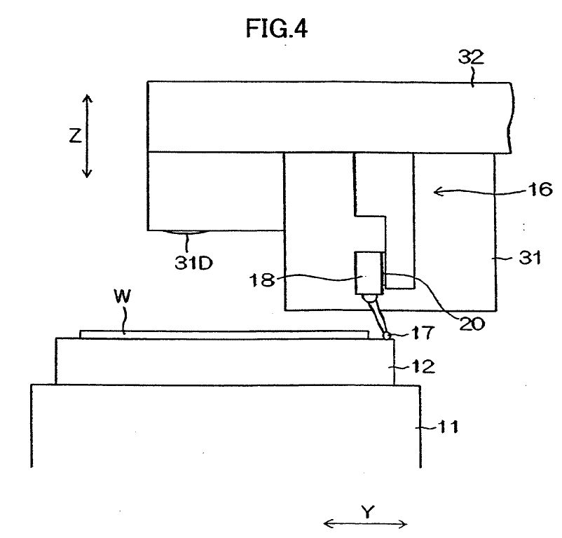

FIG. 4 is a side view for explaining the construction of the measuring device. The measuring device 16 is attached to a side surface portion of the laser head 31 and is moved in the Y-direction and in the Z-direction by the Y-table and the Z-table like the laser head 31.

The measuring device 16 is provided with a contact-type displacement measuring device 18, which is vertically moved in the Z-direction by an air cylinder 20 and has a measuring probe 17 retracted from the measurement plane when measuring is not performed.

When laser dicing is performed on the wafer W with the laser dicing apparatus 10 of the present invention, the wafer W is ordinarily mounted on a dicing frame F by means of a dicing tape T having an adhesive on its one surface, as shown in FIG. 6, and is transported in this state during a laser dicing process.

The measuring device 16 measures the difference between the position of the surface of the dicing tape T adhered to the wafer W mounted on the chuck table 12 and the position of the wafer W surface while moving the measuring probe 17 in the X-direction and in the Y-direction, and measures the thickness of the wafer W from the difference between the positions. The measured thickness of the wafer W is sent to the control device 21 to undergo processing.

Thus, even in a case where wafers W varying in thickness are successively supplied to the laser dicing apparatus 10, the wafer thickness is automatically measured and laser dicing is performed by selecting optimum modified region forming conditions from the database stored in the recording device 22 in advance.

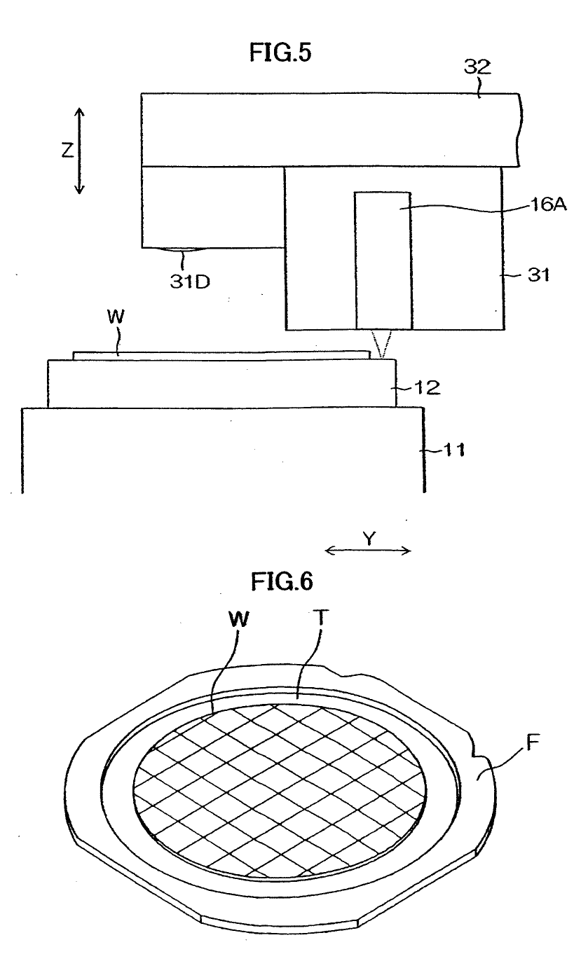

As the measuring device 16, a noncontact-type measuring device 16A such as a laser displacement meter or an IR camera may be used, as shown in FIG. 5.

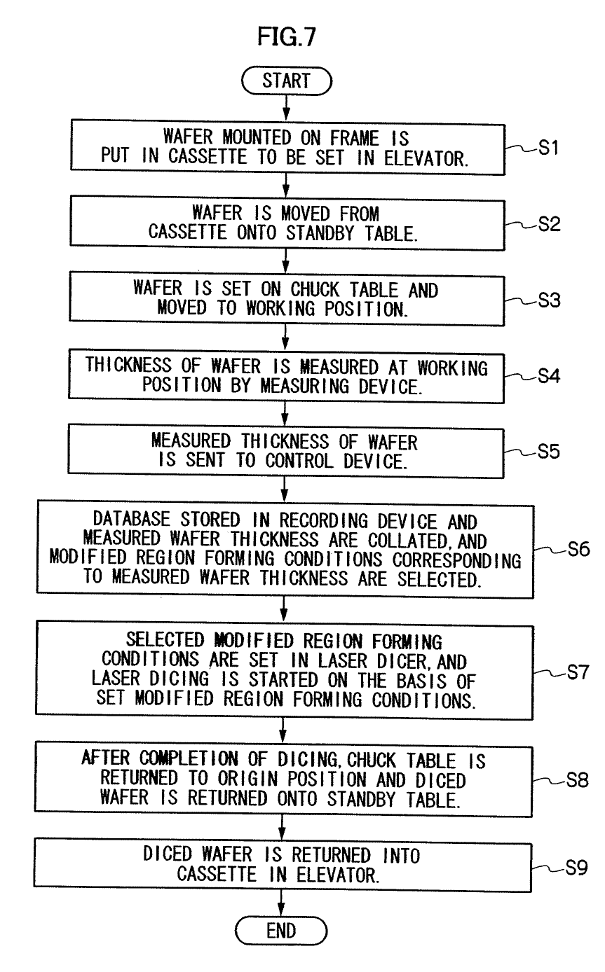

A laser dicing method using the laser dicing apparatus according to the present invention will next be described. FIG. 7 is a flowchart of the laser dicing method according to the present invention.

In the laser dicing apparatus 10, wafer W adhered to the dicing tape T shown in FIG. 6 and mounted on the frame F is housed in a cassette, and the cassette is set in the elevator 13 (step S1).

If there is a need to input working data such as the wafer size and the indexing amount, setting is made at this point in time by inputting such data through the operation panel not illustrated. After setting, an operation to input a command to start working is performed to start working, and the elevator 13 starts moving.

The wafer W mounted on the frame F is transported from the elevator 13 moved to a predetermined height onto the standby table 14 by the transport device not illustrated (step 2).

On the standby table 14, various processings required before working, such as cleaning of the wafer W surface, checking the size of the wafer W and cracks in the wafer W and checking the position of an alignment mark, are performed.

After the completion of processings on the standby table 14, the wafer W is placed on the chuck table 12 positioned at the origin position by being transported by the transport device not illustrated, and the chuck table 12 is moved in the X-direction by the X-table. The chuck table 12 is thereby moved to a working position below the Y-guide base 41 (step S3).

The thickness of the wafer W on the chuck table 12 moved to the working position is measured by the measuring device 16 (step S4).

In wafer W thickness measurement, the Z-tables and the air cylinders 20 shown in FIG. 4 are lowered in the Z-direction and the X- and Y-tables are moved to bring the measuring probe 17 into contact with the surface of the dicing tape T. The position of the dicing tape T surface is thereby set as a reference position.

After setting the reference position, the measuring probe 17 is moved in the X-direction and in the Y-direction to be brought into contact with the surface of the water W. The position of the dicing tape T surface and the position of the wafer W surface are thereby measured and the value of the thickness of the wafer W is measured from the difference therebetween. Measurement of the thickness of the wafer W is performed on one place in the wafer W, on a plurality of portions or on all lines along which laser dicing is performed.

The measured value of the thickness of the wafer W is sent to the control device 21 to undergo processing (step S5).

The measured value of the thickness of the wafer W sent to the control device 21 is collated with the database stored in the recording device 22, and the modified region forming conditions corresponding to the measured thickness of the wafer W are selected from the modified region forming conditions associated with the thicknesses of the wafer W described in the database (step S6).

The modified region forming conditions include the number of modified regions to be formed, the positions of the modified regions to be formed, the thickness of the modified regions to be formed, the speed at which the laser light is moved, the frequency of the laser light and the shape of the laser light. The modified region forming conditions are described in the database with respect to each of all wafer W thicknesses assumed.

The selected modified region forming conditions are set in the laser dicing apparatus 10 by the controller 21 and laser dicing is started on the basis of the set conditions (step S7).

After the completion of laser dicing, the chuck table is returned to the origin position and the laser-diced wafer W is returned onto the standby table 14 by the transport device (step S8).

On the standby table 14, various processings required after working, such as expanding of the wafer W, cleaning of the wafer W and checking the wafer surface, are performed.

After the processings on the standby table 14, the wafer W is returned to the cassette by the transport device. After the completion of working on all wafers W, the elevator 13 moves to the cassette taking out position and working ends (step S9).

Thus, the thickness of each wafer W is measured and laser dicing is performed by selecting the optimum modified region forming conditions from the database stored in the recording device 22 in advance.

While in the present invention the wafer W is mounted on the chuck table 12 and the thickness of the wafer W is measured at the working position, the present invention is not limited to this; the measuring device 16 may be provided in the vicinity of the standby table 14 to measure the thickness of the wafer W on the standby table 14.

In the laser dicing apparatus and laser dicing method according to the present invention, as described above, the wafer thickness is automatically measured to set the optimum modified region forming conditions, so that even in a case where wafers varying in thickness are successively supplied to the laser dicing apparatus, high-quality dicing can be speedily performed without causing a working defect due to an abrupt change in thickness.

The present invention has been described with respect to an apparatus of a construction such as that of the laser dicing apparatus 10 shown in FIG. 1. However, the present invention is not limited to this. The present invention can be suitably applied to any apparatus capable of performing dicing by using laser light.

1. A laser dicing apparatus which introduces laser light through a surface of a wafer to form a modified region in the wafer, the laser dicing apparatus characterized by comprising:
a measuring device which measures thickness of the wafer;
a recording device which stores a database in which modified region forming conditions associated with different thicknesses of the wafer are described;
a control device which controls the laser dicing apparatus by automatically selecting the modified region forming conditions corresponding to the thickness of the wafer from the database on the basis of the thickness of the wafer measured by the measuring device; and
a laser head which applies the laser light, and the laser dicing apparatus also characterized in that
the laser head comprises a laser oscillation device, a light parallelizing device, a reflecting device, a light condensing device and a light inclining device; laser light oscillated from the laser oscillation device is applied to the wafer by being formed into parallel rays in a horizontal direction by the light parallelizing device, reflected in a vertical direction by the reflecting device, condensed by the light condensing device and inclined at an arbitrary angle by the light inclining device.

2. The laser dicing apparatus according to claim 1, characterized in that the modified region forming conditions are a number of the modified regions to be formed, positions of the modified regions to be formed, thickness of the modified regions to be formed, speed at which the laser light is moved, frequency of the laser light and shape of the laser light.

3. A laser dicing method in which laser light is introduced through a surface of a wafer to form a modified region in the wafer, the laser dicing method characterized in that
the wafer mounted on a frame by means of a tape is housed in a cassette, the cassette is set in an elevator, a first transport device transports the wafer mounted on the frame from the elevator onto a standby table, and a second transport device transports the wafer from the standby table onto a chuck table;
a measuring device measures the thickness of the wafer by setting a surface of the tape as a reference position and measuring the difference between the surface of the wafer and the tape surface; and
the controls device automatically selects, on the basis of the thickness of the wafer measured by the measuring device, from modified region forming conditions associated with different thicknesses of the wafer and described in a database stored in recording device in advance, and laser dicing is performed under the selected modified region forming conditions.
